(19) United States
(12) Patent Application Publication
(10) Pub. No.: US 2023/0319958 A1
(43) Pub. Date: Oct. 5, 2023

(54) MODE SHAPING IN MICROWAVE OVENS USING ELECTROMAGNETIC METAMATERIALS AND METASURFACES

(71) Applicant: Meta Materials Inc., Boxborough, MA (US)

(72) Inventor: Yaroslav A. Urzhumov, Dublin, CA (US)

(21) Appl. No.: 17/710,696

(22) Filed: Mar. 31, 2022

(51) Int. Cl. H05B 6/74; H05K 9/00; H05B 6/64

(52) U.S. Cl. CPC H05B 6/74; H05K 9/0056; H05B 6/6402

(57) ABSTRACT

Systems and methods for facilitating substantially uniform dielectric heating capacities. In one aspect, a microwave device comprises a microwave power source and a microwave cavity. The microwave cavity comprises a plurality of surfaces, an empty domain, and a feed connected to the microwave power source for receiving microwave energy from the microwave power source to create a microwave field distribution within the microwave cavity. The microwave device also comprises a plurality of electromagnetic metamaterial layers disposed at different orientations with respect to a surface of the microwave cavity. The plurality of electromagnetic metamaterial layers affect the microwave field distribution and forming a substantially spatially uniform, time-averaged electric field intensity throughout the empty domain of the microwave cavity from the microwave energy.

### FIELD OF THE INVENTION

The present application relates to the field of microwave heating. More particularly, the present application relates to systems and methods for facilitating substantially uniform microwave heating capacities.

### BACKGROUND OF THE INVENTION

Uneven microwave heating of food in microwave ovens presents a food safety issue due to the occurrence of undercooked food regions. Previously proposed solutions do not address fundamental problems with electromagnetic heating of food inside sub-wavelength electromagnetic cavities.

Specifically, penetration of electromagnetic fields into food items is limited by the electromagnetic skin depth, which is a function of frequency and material conductivity. Using a lower frequency leads to an increased skin depth and hence more uniform heat generation inside food items. However, conventional cavities do not allow the use of frequencies that correspond to free-space wavelengths more than twice the minimum dimension of the cavity, due to the fundamental cut-off frequency of the cavity with electrically conductive walls.

Additionally, a diminished electric field in the vicinity of conducting walls can lead to uneven electromagnetic heating. This issue is a fundamental property of subwavelength cavities with electrically conducting walls, and it arises from the boundary condition at the walls that create vanishing tangential electrical fields. Combined with the subwavelength dimensions of such cavities, as well as the small or zero number of eigenmodes that are supported by such cavities, the electric energy density created within the cavity is non-uniform. In particular, the electric energy density varies with a strong deviation from its mean value near at least one pair of conducting walls. Further, when the subwavelength cavity supports no eigenmodes, which is the case with deeply subwavelength cavities (less than half-wavelength in each dimension), electric energy density decays rapidly (exponentially) as a function of the distance from the power injection port.

Current methods for improving heat generation in microwave ovens, e.g., creating more heating uniformity, involve complicated mechanical solutions. Specifically, mechanical solutions that include rotating parts, e.g., a rotating table on which the cookware is placed or rotating mode stirrers hidden behind an electromagnetically transparent wall, have been implemented to improve heating uniformity. Such mechanical solutions, however, are deficient for a number of reasons. First, such mechanical solutions are not fully efficient in providing uniform heating. Additionally, such mechanical solutions, introduce additional issues, such as extra energy consumption, extra noise, accidental food displacement, and food spillover. Furthermore, mechanical solutions with turntables limit the useful volume of the oven to a cylindrical subdomain within the electromagnetic cavity. Other solutions for improving heat generation involve time-dependent coupling of a feed to different modes of the cavity. However, these solutions can be inefficient, particularly in cavities that support only very few eigenmodes. Further, these solutions use additional electromagnetic components that can both increase the cost of the oven and decrease the reliability of the oven.

### SUMMARY OF THE INVENTION

It has been discovered that metamaterial layers can affect a microwave field distribution. It has also been discovered that metamaterial layers can affect a cut-off frequency of a microwave cavity.

This discovery has been exploited to develop the present disclosure, which, in part, is directed to creating a substantially uniform microwave field distribution within a microwave cavity. Further, this discovery has been exploited to develop the present disclosure, which, in part, is also directed to a microwave cavity that supports propagation of a microwave field that is greater than twice a minimum dimension of the microwave cavity.

In one aspect, the present disclosure is directed to a microwave device comprising a microwave power source and a microwave cavity. The microwave cavity comprises a plurality of surfaces, an empty domain, and a feed connected to the microwave power source for receiving microwave energy from the microwave power source to create a microwave field distribution within the microwave cavity. The microwave device also comprises a plurality of electromagnetic metamaterial layers disposed at different orientations with respect to a surface of the microwave cavity. The plurality of electromagnetic metamaterial layers affect the microwave field distribution and forming a substantially spatially uniform, time-averaged electric field intensity throughout the empty domain of the microwave cavity from the microwave energy.

In an embodiment, the substantially spatially uniform time-averaged electric field intensity is within a range of about 15%, about 25%, or about 30% of a spatial mean of the electric field intensity over the empty domain of the microwave cavity.

In another embodiment, an electromagnetic metamaterial layer of the plurality of electromagnetic metamaterial layers comprises an artificial magnetic material or a magnetic metamaterial.

In yet another embodiment, an electromagnetic metamaterial layer of the plurality of electromagnetic metamaterial layers comprises an electrically insulating substrate with electrically conductive lines, the conductive lines patterned to produce an artificially-magnetic effective response.

In an embodiment, an electromagnetic metamaterial layer of the plurality of electromagnetic metamaterial layers comprises an artificial magnetic surface or a magnetic metasurface.

In another embodiment, an electromagnetic metamaterial layer of the plurality of electromagnetic metamaterial layers comprises a high impedance metamaterial.

In yet another embodiment, the plurality of electromagnetic metamaterial layers comprise one or more materials that allow tangential electric fields to exist on the surface of metamaterial layers, while concurrently reflecting electromagnetic waves back into the cavity thus substantially confining electromagnetic fields to the empty domain of the cavity.

In an embodiment, the plurality of electromagnetic metamaterial layers reduce the Voltage Standing Wave ratio (herein “VSWR”) of a standing wave pattern of the microwave field distribution as part of forming the substantially spatially uniform, time-averaged, electric field intensity throughout the empty domain of the microwave cavity.

In another embodiment, an electromagnetic property of an electromagnetic metamaterial layer of the plurality of electromagnetic metamaterial layers comprises a magnetic resonance, the magnetic resonance providing a large magnitude of a complex effective magnetic permeability for at least one component of a magnetic field of the electromagnetic metamaterial layer.

In yet another embodiment, the large magnitude of the complex effective magnetic permeability is due, at least in part, to a large positive real part of the complex effective magnetic permeability.

In an embodiment, the large magnitude of the complex effective magnetic permeability is due, at least in part, to a large negative real part of the complex effective magnetic permeability.

In another embodiment, the large magnitude of the complex effective magnetic permeability is due, at least in part, to a large magnitude of an imaginary part of the complex effective magnetic permeability.

In yet another embodiment, an electromagnetic property of an electromagnetic metamaterial layer of the plurality of electromagnetic metamaterial layers comprises an electromagnetic resonance, the electromagnetic resonance providing a small magnitude of a complex effective dielectric permittivity for at least one component of an electric field of the electromagnetic metamaterial layer.

In an embodiment, the small magnitude of the complex effective dielectric permittivity is due, at least in part, to a vanishing effective electrical conductivity for an in-plane component of the electric field.

In another embodiment, the plurality of electromagnetic metamaterial layers comprises one pair of electromagnetic metamaterial layers, two pairs of electromagnetic metamaterial layers, or three pairs of electromagnetic metamaterial layers, and the metamaterial layers in each pair of electromagnetic metamaterial layers are positioned substantially parallel with respect to each other.

In yet another embodiment, the plurality of electromagnetic metamaterial layers are integrated as part of corresponding different surfaces of the plurality of surfaces of the microwave cavity.

In an embodiment, an electromagnetic metamaterial layer of the plurality of electromagnetic metamaterial layers comprises an optically transparent metamaterial layer.

In another embodiment, the optically transparent metamaterial layer comprises an optically transparent substrate with electrically conductive lines, each electrically conductive line having a thickness small enough such that each electrically conductive line is substantially invisible to a naked human eye.

In yet another embodiment, the microwave cavity comprises a plurality of electromagnetic shielding layers positioned exterior to the plurality of metamaterial layers.

In an embodiment, the feed connected to the microwave power source is positioned on a wall of the microwave cavity to affect the electric field intensity in creating the substantially spatially uniform, time-averaged electric field intensity through the empty domain of the microwave cavity.

In another embodiment, the feed connected to the microwave power source includes a transition from a conventional RF transmission line to an opening in a wall of the microwave cavity, the substantially spatially uniform, time-averaged electric field intensity formed over the opening.

In yet another embodiment, the transition further includes an electromagnetic metamaterial layer.

In an embodiment, the plurality of electromagnetic metamaterial layers affect a cut-off frequency of the microwave cavity to support propagation of the microwave field through the empty domain of the cavity at a wavelength of the cavity that is greater than twice a minimum dimension of the microwave cavity.

In another embodiment, the microwave power source produced power within a narrow band of a microwave spectrum of the microwave energy.

In yet another embodiment, an electromagnetic metamaterial layer of the plurality of electromagnetic metamaterial layers comprises an artificial magnetic material or a magnetic metamaterial that are artificially magnetic with respect to a narrow band of a microwave spectrum of the microwave energy.

In one aspect, the present disclosure is directed to a microwave device comprising a microwave power source and a microwave cavity. The microwave cavity comprises a plurality of surfaces, an empty domain, and a feed connected to the microwave power source for receiving microwave energy from the microwave power source to create a microwave field distribution within the microwave cavity. The microwave device also comprises a plurality of electromagnetic metamaterial layers disposed at different orientations with respect to a surface of the microwave cavity. The plurality of electromagnetic metamaterial layers affect a cut-off frequency of the microwave cavity to support propagation of the microwave field distribution through the empty domain of the microwave cavity at a wavelength of the microwave cavity that is greater than twice a minimum dimension of the microwave cavity.

In an embodiment, an operating frequency of the microwave cavity is substantially around 915 MHz, 434 MHz, 40.7 MHz, 27 MHz, 13.56 MHz, or 6.78 MHz.

In another embodiment, the plurality of electromagnetic metamaterial layers not only affect the cut-off frequency, but also affect the microwave field distribution and form a substantially spatially uniform time-averaged electric field intensity throughout the empty domain of the microwave cavity from the microwave energy.

In one aspect, the present disclosure is directed to a method of manufacturing a microwave oven comprising selecting design parameters of a plurality of electromagnetic metamaterial layers and a microwave cavity for creating a microwave field distribution within the cavity from microwave energy fed into the microwave cavity from a microwave power source. The method of manufacturing the microwave oven also comprises manufacturing the microwave oven according to the selected design parameters of the plurality of electromagnetic metamaterial layers and the microwave cavity so the plurality of electromagnetic metamaterial layers affect the microwave field distribution and form a substantially spatially uniform, time-averaged electric field intensity throughout an empty domain of the microwave cavity from the microwave energy during operation of the microwave oven.

In an embodiment, a design parameter of the plurality of design parameters is selected to affect the microwave field distribution and form the substantially spatially uniform time-averaged electric field intensity throughout the empty domain of the microwave cavity during the operation of the microwave oven.

In another embodiment, a design parameter of the plurality of design parameters is selected to affect an operating frequency of the microwave cavity to affect a cut-off frequency of the microwave cavity to support propagation of the microwave field distribution through the empty domain of the microwave cavity at a wavelength of the microwave cavity that is greater than twice a minimum dimension of the microwave cavity.

In yet another embodiment, the plurality of design parameters comprise characteristics for disposing an electromagnetic metamaterial layer of the plurality of electromagnetic metamaterial layers at a specific orientation with respect to a surface of a plurality of surfaces of the microwave cavity.

In an embodiment, the plurality of design parameters comprise characteristics of one pair of electromagnetic metamaterial layers, two pairs of electromagnetic metamaterial layers, or three pairs of electromagnetic metamaterial layers disposed within the microwave cavity.

In another embodiment, the plurality of design parameters include positioning each pair of electromagnetic metamaterial layers substantially parallel with respect to each other.

In one aspect, the present disclosure is directed to a method of manufacturing a microwave oven comprising selecting design parameters of a plurality of electromagnetic metamaterial layers and a microwave cavity for creating a microwave field distribution within the cavity from microwave energy fed into the microwave cavity from a microwave power source. The method of manufacturing the microwave oven also comprises manufacturing the microwave oven according to the selected design parameters of the plurality of electromagnetic metamaterial layers and the microwave cavity so the plurality of electromagnetic metamaterial layers affect a cut-off frequency of the microwave cavity to support propagation of the microwave field through the empty domain of the microwave cavity at a wavelength that is greater than twice a minimum dimension of the microwave cavity.

### DESCRIPTION OF THE DRAWINGS

The foregoing and other objects of the present disclosure, the various features thereof, as well as the disclosure itself may be more fully understood from the following description, when read together with the accompanying drawings in which:

FIG. 1 is a schematic representation of a microwave device.

FIG. 2 is a schematic representation of a microwave cavity.

FIG. 3 is a schematic representation of another microwave cavity.

FIG. 4 is a schematic representation of another microwave device.

FIG. 5 is a diagrammatic representation of a flowchart of an example method of manufacturing a microwave device.

FIG. 6 is a graphic representation of an electric field intensity distribution in a microwave cavity that lacks integration with electromagnetic metamaterial layers.

FIG. 7 is a graphic representation of an electric field intensity distribution in a microwave cavity that includes two metamaterial layers.

FIG. 8 is a graphic representation of an electric field intensity distribution in a microwave cavity that includes four metamaterial layers.

FIG. 9 is a schematic representation of an example computing system.

### DESCRIPTION

Unless defined otherwise, all technical and scientific terms used herein have the same meaning as commonly understood by one of ordinary skill in the art to which this disclosure belongs. The initial definition provided for a group or term herein applies to that group or term throughout the present specification individually or as part of another group, unless otherwise indicated.

### Definitions

“Artificially-structured materials” are materials whose electromagnetic or acoustic properties are derived from their structural configurations, rather than or in addition to their material composition.

“Metamaterials” are a type of artificially structured material that include subwavelength elements. Subwavelength elements can include structural elements with portions having spatial length scales smaller than an operating wavelength of the metamaterial. Further, the subwavelength elements have a collective response to waves or radiation that corresponds to an effective continuous medium response. For example, in the case of electromagnetic metamaterials, the collective response may be characterized by an effective permittivity, an effective permeability, an effective magnetoelectric coefficient, or any combination thereof. For example, the electromagnetic radiation may induce charges and/or currents in the subwavelength elements, and the subwavelength elements can acquire nonzero electric and/or magnetic dipole moments. Some metamaterials provide an artificial magnetic response. For example, split-ring resonators (SRRs) and other plasmonic resonators can exhibit an effective magnetic permeability. Some metamaterials have “hybrid” electromagnetic properties that emerge partially from structural characteristics of the metamaterial, and partially from intrinsic properties of the constituent materials. For example, a metamaterial consisting of a wire array embedded in a nonconducting ferrimagnetic host medium can exhibit effects of both the wire array and the host medium.

“Metamaterials” can be designed and fabricated to exhibit selected permittivity, permeability, and/or magnetoelectric coefficients values that depend upon material properties of the constituent materials as well as shapes, chirality, configurations, positions, orientations, and couplings between the subwavelength elements. The selected permittivity, permeabilities, and/or magnetoelectric coefficients values can be positive or negative, complex (having loss or gain), anisotropic, variable in space (as in a gradient index lens), variable in time (e.g. in response to an external or feedback signal), variable in frequency (e.g. in the vicinity of a resonant frequency of the metamaterial), or any combination thereof. The selected electromagnetic properties can be provided at wavelengths that range from radio wavelengths to visible wavelengths and beyond.

“Metamaterials” can include either or both discrete elements or structures and non-discrete elements or structures. For example, a metamaterial may include discrete structures, such as split-ring resonators. In another example, a metamaterial may include non-discrete elements that are inclusions, exclusions, layers, or other variations along some continuous structure.

Further, “metamaterials” can include extended structures having distributed electromagnetic responses, such as distributed inductive responses, distributed capacitive responses, and distributed inductive-capacitive responses. For example, metamaterials can include structures consisting of loaded and/or interconnected transmission lines, artificial ground plane structures, and/or interconnected/extended nanostructures.

“High-impedance metamaterials” include metamaterials that have or are capable of achieving an impedance that is a factor, e.g. at least ten times, greater than a typical metamaterial. Impedance is defined according to Equation 1.

$$Z = \sqrt{\frac{μ}{ε}} \qquad Equation 1$$

As shown in Equation 1, impedance can be increased to create a high-impedance metamaterial by achieving an increased/high μ, magnetic permeability, and/or by achieving a reduced/low ε, electric permittivity.

An “artificial magnetic material,” such as a magnetic metamaterial, is a structured medium that exhibits a magnetic response, e.g. during operation, that is different from magnetic responses of constituent materials of the structured medium. For example, magnetism in a magnetic metamaterial can emerge from a corresponding structure of the metamaterial, as opposed to solely emerging from atomic-scale magnetism. A magnetic metamaterial is a structured medium with an increased or otherwise high magnetic permeability. For example, a magnetic metamaterial can have a magnetic permeability that is a factor, e.g. at least ten times, greater than a non-magnetic metamaterial.

An “artificially-magnetic effective response” is a magnetic response that is created in an artificial magnetic material. Specifically, an artificially-magnetic effective response is a magnetic response that is created in an artificial magnetic material that is separate from magnetic responses of constituent materials of the artificial magnetic material. For example, an artificially-magnetic effective response can be a magnetic response that emerges from a corresponding structure of an artificial magnetic material, as opposed to emerging solely from atomic-scale magnetism.

An “Epsilon-Near-Zero metamaterial” is a metamaterial with a decreased or otherwise low electric permittivity. For example, an Epsilon-Near-Zero (ENZ) metamaterial can have an electric permittivity that is a factor, e.g. at least ten times, less than a typical conductive material.

A “metasurface” is a thin layer of a metamaterial. A thin layer of a metamaterial can include a subset of a total volume of the metamaterial. A metasurface can be approximated as an infinitely thin sheet having a surface impedance, or surface impedances for anisotropic responses. When approximated as an infinitely thin sheet the metasurface can lack a refractive index, as waves do not propagate or refract “inside” of the metasurface. Instead, the metasurface can act as a discontinuity in space.

An “empty domain,” as used herein with reference to a microwave cavity, includes a region contained within a microwave cavity. In particular, the empty domain of a microwave cavity includes the space contained within the microwave cavity that is not occupied by physical parts of the microwave. Additionally, the empty domain of a microwave cavity can include the space contained within the microwave cavity that is not occupied by food or any containers or vessels supporting the food.

“VSWR” is the ratio between the maximum and minimum voltage on a transmission line. The transmission line can be represented in cavity and thus the VSWR can include the ratio between the maximum and minimum voltage between points within the cavity that are separated by at least one-half wavelength of an operating frequency associated with the cavity.

A “large magnitude complex effective magnetic permeability of a metamaterial layer” is a permeability that is a factor, e.g. at least ten times, greater than a permeability of a typical conductive material. The magnetic permeability can be on a component basis of a magnetic field of the metamaterial layer.

An “effective magnetic permeability” of a metamaterial layer is the permeability relative to vacuum permeability.

An “effective dielectric permittivity” of a metamaterial layer is the permittivity relative to a vacuum permittivity.

“Components” of a field include both orientation and polarization of the field.

A “large positive real part of a complex effective magnetic permeability” is a positive and real part of the complex effective magnetic permeability that is a factor, e.g. at least ten times, greater than a positive real part of a complex effective magnetic permeability of a typical conductive material.

A “large negative real part of a complex effective magnetic permeability” is a negative and real part of the complex effective magnetic permeability having a magnitude that is a factor, e.g. at least ten times, greater than a magnitude of a negative real part of a complex magnetic permeability of a typical conductive material.

A “large magnitude of an imaginary part of a complex effective magnetic permeability” is a magnitude of an imaginary part of the complex effective magnetic permeability that is a factor, e.g. at least ten times, greater than a magnitude of an imaginary part of a complex effective magnetic permeability of a typical conductive material.

A “small magnitude of a complex effective dielectric permittivity of a metamaterial layer” is a magnitude of a part of the complex effective dielectric permittivity that is a factor, e.g. at least ten times, less than a magnitude of a corresponding part of a complex effective dielectric permittivity of a typical conductive material.

A “vanishing effective electrical conductivity associated with a metamaterial” is an effective electrical conductivity of a component that is much smaller, e.g. at least ten times smaller, than an effective electrical conductivity of a typical conductive material.

A “conventional transmission line” is a material or structure that is suitable for transmitting radio frequency (“RF”) power at an operating frequency.

A “transition” is an interconnection between two different mediums, e.g. two different transmission lines. A transition can have characteristics that facilitate transfer of energy between the two mediums, such as low insertion loss and high return loss.

A “propagation wavelength” of a microwave field distribution is a wavelength of a of the cavity in which the microwave field can propagate through a cavity, e.g. an empty domain of the cavity.

A “useful volume” of a microwave device, oven, or cavity is the volume where an injected microwave field intensity is between 50% and 200% of the average value of the microwave field intensity.

A “minimum dimension” of a microwave cavity is the smallest spatial dimension of the spatial dimensions that define the microwave cavity in three-dimensional space.

A “narrow band of a microwave spectrum” is a hand having less than or equal to 1% of a total bandwidth or available bandwidth of the microwave spectrum.

As used herein, the articles “a” and “an” refer to one or to more than one (i.e., to at least one) of the grammatical object of the article. By way of example, “an element” means one element or more than one element. Furthermore, use of the term “including” as well as other forms, such as “include,” “includes,” and “included,” is not limiting.

As used herein, the term “about” will be understood by persons of ordinary skill in the art and will vary to some extent on the context in which it is used. As used herein when referring to a measurable value such as an amount, a temporal duration, and the like, the term “about” is meant to encompass variations of ±20% or ±10%, including ±5%, ±1%, and ±0.1% from the specified value, as such variations are appropriate to perform the disclosed methods.

Reference will now be made to specific examples illustrating the disclosure. It is to be understood that the examples are provided to illustrate exemplary embodiments and that no limitation to the scope of the disclosure is intended thereby.

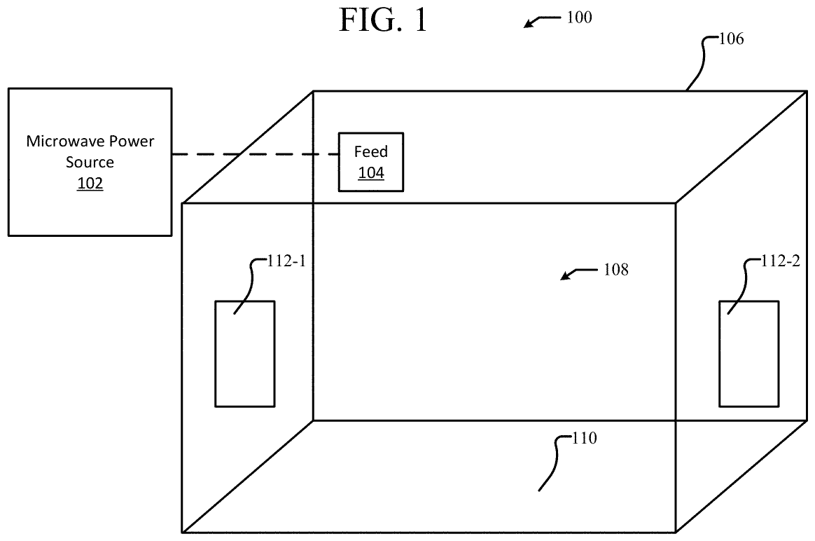

FIG. 1 is a schematic representation of a microwave device 100. The microwave device 100 can be used in providing more uniform heating of contained food. Specifically, the microwave device 100 can create a substantially uniform microwave field distribution within a microwave cavity. Further, the microwave device 100 can support a propagation of a microwave field distribution through the microwave cavity at a wavelength that is greater than twice a minimum dimension of the microwave cavity.

The microwave device 100 includes a microwave power source 102, a feed 104, and a microwave cavity 106. The microwave power source 102, the feed 104, and the microwave cavity 106 are coupled to each other so that a microwave field distribution is created within the microwave cavity 106 based on microwave energy generated by the microwave power source 102. The microwave energy generated by the microwave power source 102 can be provided to the microwave cavity 106 through the feed 104.

The microwave cavity 106 includes an empty domain 108 that is contained within the microwave cavity 106. The empty domain 108 is defined by a plurality of surfaces, e.g. surface 110, of the microwave cavity 106. The microwave cavity 106 can include an applicable number of surfaces forming an applicable shape, however, the cavity is shown as being formed by 6 surfaces in a rectangular cuboid for simplicity purposes. Further, the cavity 106 can include inner layers and outer layers. Inner layers include surfaces that define or otherwise form at least part of the contained empty domain 108. Outer layers can include those layers that do not form the surface that define the contained empty domain 108. For example, outer layers can include shielding layers that are formed around or otherwise positioned exterior to the inner layers defining the empty domain 108.

The feed 104 can be integrated as part of the microwave cavity to inject a microwave field distribution within the empty domain 108 from microwave energy generated by and received from the microwave power source 102. For example, the feed 104 can be integrated within the microwave cavity 106, e.g. next to the empty domain 108, to inject a microwave field distribution within the empty domain 108.

The microwave device 100 also includes a first electromagnetic metamaterial layer 112-1 and a second electromagnetic metamaterial layer 112-2, herein referred to as “the plurality of electromagnetic layers 112.” While each of the plurality of electromagnetic metamaterial layers 112 is shown as covering only a portion of a corresponding side of the microwave cavity 106, this is merely for illustrative purposes, and the plurality of electromagnetic metamaterial layers 112 can be sized to cover an entire corresponding side of the microwave cavity 106. The plurality of electromagnetic metamaterial layers 112 are positioned at different orientations with respect to one or more surfaces, e.g. the surface 110 of the microwave cavity 106. An orientation of an electromagnetic layer to a surface can include either or both a physical position and a direction of the electromagnetic layer relative to a point, axes, plane, or volume of a surface. For example, the first electromagnetic metamaterial layer 112-1 can be positioned at a first position with respect to a plane formed by the surface 110 while the second electromagnetic metamaterial layer 112-2 can be positioned at a second position with respect to the plane formed by the surface 110.

Electromagnetic metamaterial layers included in microwave devices according to the technology described herein can be implemented as part of the surfaces, e.g. inner surfaces, defining microwave cavities of the microwave devices. For example, each of the plurality of electromagnetic metamaterial layers 112 can be integrated as part of the walls of the microwave cavity 106 to form, at least in part, inner surfaces of the microwave cavity 106. Further, electromagnetic metamaterial layers included in microwave devices according to the technology described herein can be disposed within a defined microwave cavity. For example, the plurality of electromagnetic metamaterial layers 112 can be positioned away from the inner surfaces of the microwave cavity 106 in the volume contained by the microwave cavity 106.

Electromagnetic layers included in the microwave device 100 can correspond to each other as part of groups, e.g. pairs, of electromagnetic layers. Specifically, electromagnetic layers can correspond to each other based on a shared or related factor. For example, the first electromagnetic metamaterial layer 112-1 and the second electromagnetic metamaterial layer 112-2 can be substantially parallel to each other. Further in the example, while the first electromagnetic metamaterial layer 112-1 and the second electromagnetic metamaterial layer 112-2 are substantially parallel to each other, they still have different positions with respect to a plurality of surfaces, e.g. the surface 110, of the microwave device 100.

The plurality of electromagnetic metamaterial layers 112 can affect a microwave field distribution created in, otherwise injected into, the microwave cavity 106. Specifically, the plurality of electromagnetic metamaterial layers 112 can affect a microwave field distribution that is created in the empty domain 108 of the microwave cavity 106. In affecting a microwave field distribution, the plurality of electromagnetic metamaterial layers 112 can modify one or more components of a microwave field distribution. Specifically, the plurality of electromagnetic metamaterial layers 112 can modify the one or more components in comparison to a microwave field distribution injected into a microwave device that is the same as the microwave device 100 but lacking the plurality of electromagnetic metamaterial layers 112.

In affecting a microwave field distribution injected into the cavity 106, the plurality of electromagnetic metamaterial layers 112 can form a substantially spatially uniform time-averaged electric field intensity throughout the empty domain 108 of the microwave cavity 106. Specifically, the plurality of electromagnetic metamaterial layers 112 can form a substantially uniform time-averaged electric field intensity throughout the empty domain 108 from microwave energy that is generated by the microwave power source 102 and fed into the microwave cavity 106 from the feed 104. A substantially uniform time-averaged electric field intensity includes electric field intensities at various points, lines, planes, or volumes in the empty domain 108 in relation to a spatial mean of the electric field intensity of the field over either a subset of the empty domain 108 or the entire empty domain 108. Specifically, a substantially uniform time-averaged electric field intensity includes electric field intensities that are within a range, e.g. about 15%, 25%, or 30%, of a spatial mean of the electric field intensity of the field over either a subset of the empty domain 108 or the entire empty domain 108.

Affecting a microwave field distribution to create a substantially uniform time-averaged electric field intensity throughout the empty domain 108 is advantageous as it can lead to more uniform food cooking during operation of the microwave device 100. Specifically, creating a substantially uniform time-averaged electric field intensity throughout the empty domain 108 can create a more uniform electric field intensity throughout an item that is positioned in the empty domain 108 and heated up during operation of the microwave device 100. As a result, cooking times can be decreased and food can be cooked at a reduced power consumption.

Creating a substantially uniform time-averaged electric field intensity is in contrast to a field distribution created in a typical microwave device that lacks metamaterial layers integrated with the cavity. In particular, a typical microwave device injects a non-uniform microwave field distribution into a cavity, leading to uneven heating of an item. This non-uniform microwave field distribution is created, in part, by boundary properties of electrical conductors that typically form the surfaces that define the empty domain of a microwave cavity. In particular, in an idealized version of an electric conductor, a perfect electric conductor (“PEC”), a tangential electric field vanishes at a surface of the conductor. This decreased, or otherwise vanishing of the tangential electric field creates the non-uniform electric field within a microwave cavity formed by electrical conducts. Specifically, an idealized model of a microwave cavity formed by 6 PEC walls supports only a small number of eigenmodes, none of which have a uniform electric field due to these boundary properties of a PEC.

In contrast, a magnetic dual of a PEC, otherwise referred to as a perfect magnetic conductor (“PMC”), causes a tangential magnetic field to vanish on a surface of the PMC while allowing a tangential electric field to be non-zero at the surface. Accordingly, a more uniform electric field distribution can be created in relation to the PMC. Specifically, if two walls, e.g. opposite walls, in a microwave cavity formed by 6 conductors are replaced with PMC surfaces, then the cavity can support a mode where an electric field distribution is uniform around the PMC surfaces and tangential to the PMC surfaces. Further, the cavity behaves, from the viewpoint of a corresponding eigenmode spectrum, as an infinite rectangular waveguide with PEC walls. Additionally, this creates a tangential electric field mode of the waveguide, while the magnetic field forms a standing wave defined by the PMC boundaries.

The plurality of electromagnetic metamaterial layers 112 can have the same or similar effects on the microwave field distribution in the microwave cavity 106 as the discussed PMCs. Specifically, the plurality of electromagnetic metamaterial layers 112 can allow tangential electric fields to exist on the surface of metamaterial layers, while concurrently reflecting electromagnetic waves back into the cavity. In turn, this can confine, at least substantially, electromagnetic fields to an interior of the cavity, e.g. the empty domain 108. Further, the plurality of electromagnetic metamaterial layers 112 can reduce a VSWR of a standing wave pattern of the microwave field distribution. Accordingly, these effects on the microwave field distribution can lead to the formation of a substantially-spatially uniform time averaged electric field intensity through the empty domain 108.

The plurality of electromagnetic metamaterial layers 112 can also affect a cut-off frequency of the microwave cavity 106. A cut-off frequency of the microwave cavity 106, otherwise referred to as a fundamental frequency, is a frequency of the microwave cavity 106 at which the microwave cavity 106 can still operate at in supporting a microwave field distribution within the cavity 106. The plurality of electromagnetic metamaterial layers 112 can affect a cut-off frequency of the microwave cavity 106 to support propagation of a microwave field distribution through the empty domain 108 at a wavelength of the microwave cavity 106 that is greater than twice a minimum dimension of the microwave cavity 106. For example, the microwave cavity 106, based on incorporation of the plurality of electromagnetic metamaterial layers 112 can have an operating frequency that is substantially around 915 MHz, 434 MHz, 40.7 MHz, 27 MHz, 13.56 MHz, or 6.78 MHz.

By affecting the cut-off frequency to support a propagation wavelength of a microwave field distribution that is greater than twice a minimum dimension of the microwave cavity 106, an operating frequency of the microwave device 100 can be effectively lowered. Specifically, microwave energy can be injected into the microwave cavity 106 at a lower frequency to create a microwave field distribution at a lower frequency relative to a microwave cavity that lacks electromagnetic metamaterial layers. This can allow for an increased penetration depth of the microwave field distribution with respect to a food item, thereby providing more uniform heating of the food item. This can also reduce power consumption used in heating a food item in the microwave device 100.

The plurality of electromagnetic metamaterial layers 112 can be formed by artificial magnetic materials, such as magnetic metamaterials. Further, the plurality of electromagnetic metamaterial layers 112 can be formed by layers that comprise insulating substrates with electrically conductive lines. The conductive lines can be patterned to produce an artificially-magnetic effective response. Additionally, the plurality of electromagnetic metamaterial layers 112 can comprise an artificial magnetic surface, such as a magnetic metasurface. The plurality of electromagnetic metamaterial layers 112 can also comprise a high impedance metamaterial. Including any of these materials and surfaces, either alone or in combination, in the plurality of electromagnetic layers 112 can affect either or both a microwave field distribution of the microwave cavity 106 or a cut-off frequency of the cavity 106 according to the technology described herein.

Further, the plurality of electromagnetic metamaterial layers 112 can have properties that ultimately affect either or both a microwave field distribution of the microwave cavity 106 or a cut-off frequency of the cavity 106. Specifically, an electromagnetic metamaterial layer of the plurality of electromagnetic metamaterial layers 112 can have a magnetic resonance that provides a large magnitude of a complex effective magnetic permeability for a component of a magnetic field of the plurality of electromagnetic metamaterial layers 112. The large magnitude of the complex effective magnetic permeability can be created from a large positive real part of the complex effective magnetic permeability, a large negative real part of the complex effective magnetic permeability, a large magnitude of an imaginary part of the complex effective magnetic permeability, or a combination thereof.

An electromagnetic metamaterial layer of the plurality of electromagnetic metamaterial layers 112 can have an electromagnetic resonance that provides a small magnitude of a complex effective dielectric permittivity for a component of an electric field of the electromagnetic layer. The small magnitude of the complex effective dielectric permittivity can be created as part of a vanishing effective electrical conductivity associated with the electric field. Specifically, the small magnitude of the complex effective dielectric permittivity can be created as part of a vanishing effective electrical conductivity of an in-plane component of the electric field.

The plurality of electromagnetic metamaterial layers 112 can be formed from one or more optically transparent metamaterials. For example, an electromagnetic metamaterial layer of the electromagnetic metamaterial layers 112 can be formed by a structured NANOWEB® layer. U.S. Pat. No. 9,465,296B2, “Nanopatterning method and apparatus” and “Rolling mask nanolithography: the pathway to large area and low cost nanofabrication,” Proceedings of SPIE Volume 8249, Advanced Fabrication Technologies for Micro/Nano Optics and Photonics V: 82490O (2012), which are both hereby incorporated by reference in their entirety, provide examples of electromagnetic metamaterial layers that can be used in the technology described herein.

In including an optically transparent metamaterial, the plurality of electromagnetic metamaterial layers 112 can be formed from an optically transparent substrate with electrically conductive lines formed in the optically transparent substrate. Either or both the substrate and the electrically conductive lines can have characteristics that make either or both the substrate and the electrically conductive lines substantially invisible to a naked human eye. For example, an electrically conductive line formed in an optically transparent substrate can have a thickness that is small enough, e.g. between 0.5 μm and 10 μm. The optically transparent metamaterials can be fabricated according to an applicable technique. For example, Rolling Mask Lithography (“RML”) allows such metamaterials and metasurfaces to be implemented in a miniaturized form-factor, due to its ability to pack loops of micro or nanowires into a smaller area in a form that is nearly invisible to the naked eye.

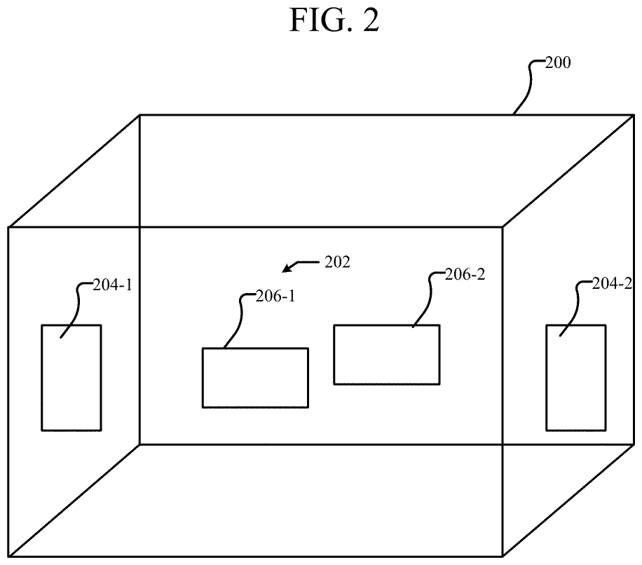

FIG. 2 is a schematic representation of a microwave cavity 200. The microwave cavity 200 can be integrated as part of an applicable microwave device, such as the microwave device 100, to implement the technology described herein.

The microwave cavity 200 includes an empty domain 202 that is defined by surfaces of the microwave cavity 200. The microwave cavity 200 also includes a first electromagnetic metamaterial layer 204-1 and a second electromagnetic layer 204-2, herein referred to as “the first pair of electromagnetic metamaterial layers 204.” The microwave cavity 200 includes a third electromagnetic metamaterial layer 206-1 and a fourth electromagnetic metamaterial layer 206-2, herein referred to as “the second pair of electromagnetic metamaterial layers 206.” The first pair of electromagnetic metamaterial layers 204 and the second pair of electromagnetic metamaterial layers 206 can function to affect either or both a microwave field distribution created in the empty domain 202 and a cut-off frequency of the microwave cavity 200 according to the technology described herein.

Each electromagnetic metamaterial layer in the first pair of electromagnetic metamaterial layers 204 and the second pair of electromagnetic metamaterial layers 206 can be positioned at different orientations with respect to one or more surfaces of the microwave cavity 200. Specifically, the first pair of electromagnetic metamaterial layers 204 can be implemented as part of corresponding opposing surfaces of the microwave cavity 200 while the second pair of electromagnetic metamaterial layers 206 can be implemented as part of a separate pair of corresponding opposing surfaces of the microwave cavity 200. As a result of this placement, the microwave cavity 200 can behave as a parallel-plate waveguide that is effectively infinite in two dimensions and bounded by two PEC surfaces, corresponding to the surfaces lacking metamaterial layers. This waveguide supports a mode with an electric field that is normal to the two PEC surfaces, which corresponds to the mode(s) of interest in the cavity 200.

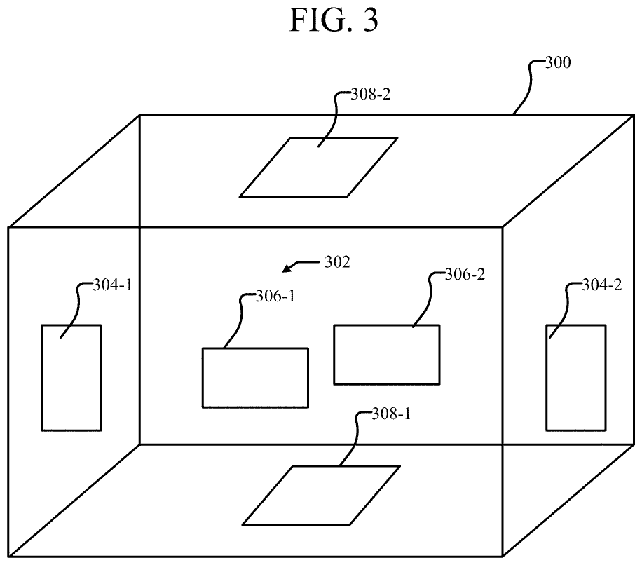

FIG. 3 is a schematic representation of another microwave cavity 300. The microwave cavity 300 can be integrated as part of an applicable microwave device, such as the microwave device 100, to implement the technology described herein.

The microwave cavity 300 includes an empty domain 302 that is defined by surfaces of the microwave cavity 300. The microwave cavity 300 also includes a first electromagnetic metamaterial layer 304-1 and a second electromagnetic layer 304-2, herein referred to as “the first pair of electromagnetic metamaterial layers 304.” The microwave cavity 300 includes a third electromagnetic metamaterial layer 306-1 and a fourth electromagnetic metamaterial layer 306-2, herein referred to as “the second pair of electromagnetic metamaterial layers 306.” The microwave cavity 300 also includes a fifth electromagnetic metamaterial layer 308-1 and a sixth electromagnetic metamaterial layer 308-2, herein referred to as “the third pair of electromagnetic metamaterial layers 308.” The first pair of electromagnetic metamaterial layers 304, the second pair of electromagnetic metamaterial layers 306, and the third pair of electromagnetic metamaterial layers 308 can function to affect either or both a microwave field distribution created in the empty domain 302 and a cut-off frequency of the microwave cavity 300 according to the technology described herein.

Each electromagnetic metamaterial layer in the first pair of electromagnetic metamaterial layers 304, the second pair of electromagnetic metamaterial layers 306, and the third pair of electromagnetic metamaterial layers 308 can be positioned at different orientations with respect to one or more surfaces of the microwave cavity 300. Specifically, the first pair of electromagnetic metamaterial layers 304 can be implemented as part of a first pair of corresponding opposing surfaces of the microwave cavity 300, the second pair of electromagnetic metamaterial layers 306 can be implemented as part of a second pair of corresponding opposing surfaces of the microwave cavity 300, and the third pair of electromagnetic metamaterial layers 308 can be implemented as part of a third pair of corresponding opposing surfaces of the microwave cavity 300.

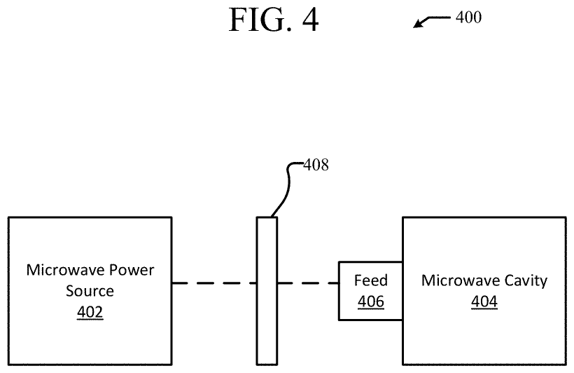

FIG. 4 is a schematic representation of another microwave device 400. The microwave device can operate as an applicable microwave device for implementing the technology described here, such as the microwave device 100.

The microwave device 400 includes a microwave power source 402 and a microwave cavity 404. The microwave cavity is coupled to the microwave power source 402 through a feed 406. The feed 406 can be positioned on a wall/surface of the microwave cavity 404 to affect an electrical field intensity in creating a substantially spatially uniform time-averaged electric field intensity in at least a portion of an empty domain of the microwave cavity 404. For example, the feed 406 can be placed symmetrically about a center of symmetry of a wall of the microwave cavity 404.

The feed 406 is coupled to the microwave power source 402 through a transition 408. The transition 408 can be a transition from a conventional RF transmission line. For example, the transition 408 can be from a rectangular waveguide, a circular waveguide, or a coaxial cable. Further, the transition 408 can be a transition into an opening in a wall of the microwave cavity 404. For example, the transition 408 can be a transition from a waveguide to an opening in the wall of the microwave cavity 404. Additionally, a substantially spatially uniform time-averaged electric field intensity can be created over an opening in the wall that serves as the transition 408.

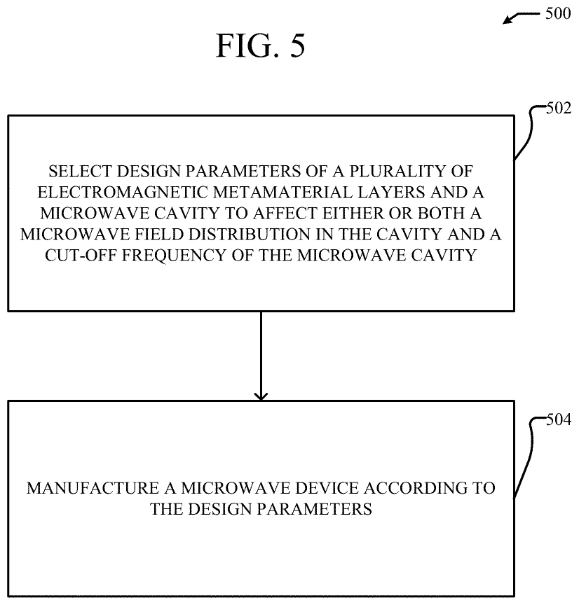

FIG. 5 is a diagrammatic representation of a flowchart 500 of an example method of manufacturing a microwave device. The method shown in FIG. 5 is provided by way of example, as there are a variety of ways to carry out the method. Additionally, while the example method is illustrated with a particular order of steps, those of ordinary skill in the art will appreciate that FIG. 5 and the modules shown therein can be executed in any order and can include fewer or more modules than illustrated. Further, each module shown in FIG. 5 represents one or more steps, processes, methods or routines in the method.

At module 502, design parameters of a plurality of electromagnetic metamaterial layers and a microwave cavity are selected to affect either or both a microwave field distribution in the cavity and cut-off frequency of the microwave cavity. Specifically, the design parameters can be selected to affect a microwave field distribution and create a substantially spatially uniform time-averaged electric field intensity in the microwave cavity during operation. Further, the design parameters can be selected to affect a cut-off frequency of the microwave cavity to support a propagation wavelength of the microwave field distribution in the microwave cavity during operation.

Design parameters include applicable parameters that can be selected and implemented in manufacturing a microwave oven that includes electromagnetic metamaterial layers. The design parameters can comprise characteristics for disposing an electromagnetic metamaterial layer at a specific orientation with respect to a surface in the microwave cavity. For example, a design parameter can specify to implement an electromagnetic metamaterial layer in a specific surface of the microwave cavity. In another example, a design parameter can specify to place an electromagnetic material layer in front of a surface of the microwave cavity. Additionally, the design parameters can specify whether to implement one pair of electromagnetic metamaterial layers, two pairs of electromagnetic metamaterial layers, or three pairs of electromagnetic metamaterial layers in a microwave cavity. Further, the design parameters can specify orientations of the layers in implementing the pair(s) of electromagnetic metamaterial layers, such as substantially parallel orientations with respect to each other in the pairs.

At module 504, the microwave device is manufactured according to the selected design parameters. In manufacturing the microwave device according to the selected design parameters, either or both a microwave field distribution and a cut-off frequency of the microwave oven can be affected. In turn, this can lead to more uniform cooking of food in the microwave device while using less power and in quicker times.

To further illustrate the benefits of the described technology, the disclosure continues with a discussion of simulations of traditional microwave devices and microwave devices implementing the described technology.

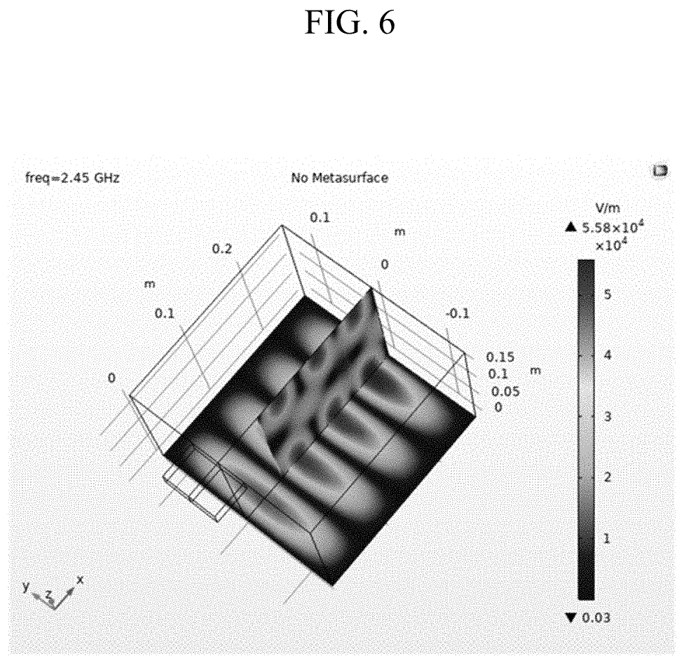

FIG. 6 is a graphic representation of an electric field intensity distribution in a microwave cavity that lacks integration with electromagnetic metamaterial layers. Specifically, the simulated microwaved cavity includes 6 electrically conducting walls. The cavity is excited with a vertically polarized mode of a rectangular waveguide injecting 1 kW power. A standing wave pattern is evident in each direction. The peak value of the electric field intensity is 56 kV/m, and the useful volume of the cavity is 58% of the cavity volume;

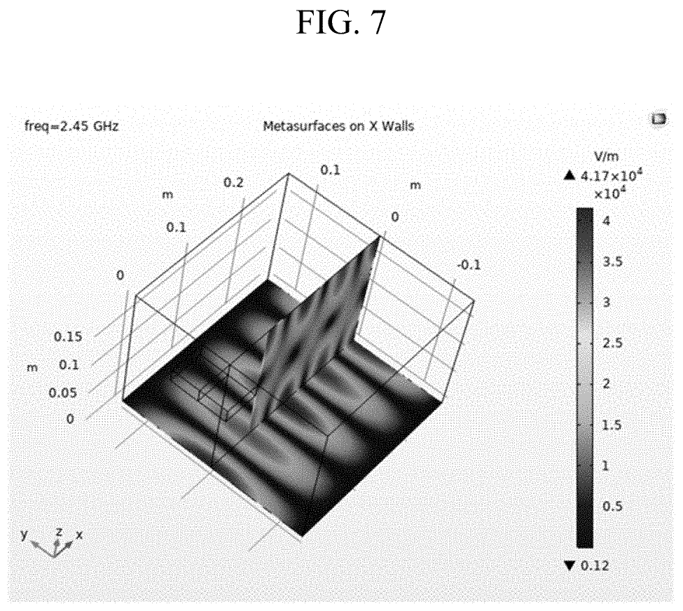

FIG. 7 is a graphic representation of an electric field intensity distribution in a microwave cavity that includes two metamaterial layers. The design of the cavity can be the same or similar to the microwave cavity 106 shown in FIG. 1. Specifically, a pair of walls orthogonal to the X axis are replaced with electromagnetic metamaterial layers. The peak value of the electric field intensity is reduced to 42 kV/m, and the useful volume of the oven is increased to 76%.

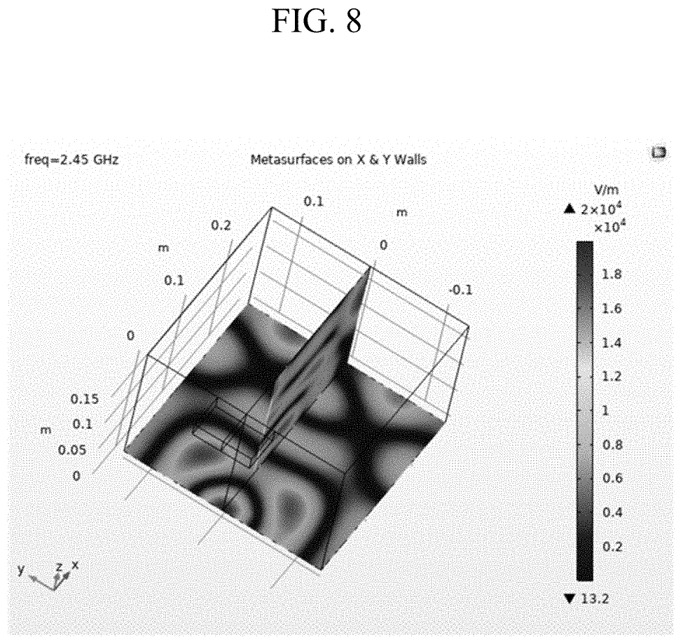

FIG. 8 is a graphic representation of an electric field intensity distribution in a microwave cavity that includes four metamaterial layers. The design of the cavity can be the same or similar to the microwave cavity 200 shown in FIG. 2. Specifically, a pair of walls orthogonal to the X axis and an additional pair of walls orthogonal to the Y axis are replaced with electromagnetic metamaterial layers. The peak value of the electric field intensity is further reduced to 20 kV/m (about ⅓ of its value in FIG. 6 representing the reference case), and the useful volume of the oven is further increased to 79% (increased by 21% from FIG. 6).

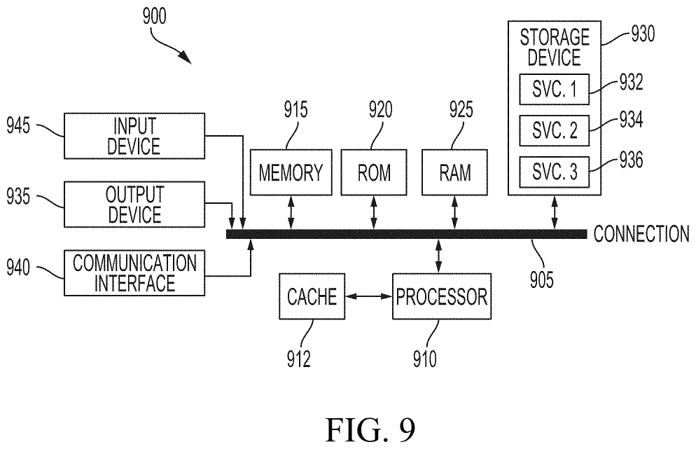

FIG. 9 is a schematic representation of a bus computing system 900 wherein the components of the system are in electrical communication with each other using a bus 905. The computing system 900 can include a processing unit (CPU or processor) 910 and a system bus 905 that may couple various system components including the system memory 915, such as read only memory (ROM) 920 and random access memory (RAM) 925, to the processor 910. The computing system 900 can include a cache 912 of high-speed memory connected directly with, in close proximity to, or integrated as part of the processor 910. The computing system 900 can copy data from the memory 915, ROM 920, RAM 925, and/or storage device 930 to the cache 912 for quick access by the processor 910. In this way, the cache 912 can provide a performance boost that avoids processor delays while waiting for data. These and other modules can control the processor 910 to perform various actions. Other system memory 915 may be available for use as well. The memory 915 can include multiple different types of memory with different performance characteristics. The processor 910 can include any general purpose processor and a hardware module or software module, such as module 1 932, module 2 934, and module 3 936 stored in the storage device 930, configured to control the processor 910 as well as a special-purpose processor where software instructions are incorporated into the actual processor design. The processor 910 may essentially be a completely self-contained computing system, containing multiple cores or processors, a bus, memory controller, cache, etc. A multi-core processor may be symmetric or asymmetric.

To enable user interaction with the computing system 900, an input device 945 can represent any number of input mechanisms, such as a microphone for speech, a touch-protected screen for gesture or graphical input, keyboard, mouse, motion input, speech and so forth. An output device 935 can also be one or more of a number of output mechanisms known to those of skill in the art. In some instances, multimodal systems can enable a user to provide multiple types of input to communicate with the computing system 900. The communications interface 940 can govern and manage the user input and system output. There may be no restriction on operating on any particular hardware arrangement and therefore the basic features here may easily be substituted for improved hardware or firmware arrangements as they are developed.

The storage device 930 can be a non-volatile memory and can be a hard disk or other types of computer readable media which can store data that are accessible by a computer, such as magnetic cassettes, flash memory cards, solid state memory devices, digital versatile disks, cartridges, random access memory, read only memory, and hybrids thereof.

As discussed above, the storage device 930 can include the software modules 932, 934, 936 for controlling the processor 910. Other hardware or software modules are contemplated. The storage device 930 can be connected to the system bus 905. In some embodiments, a hardware module that performs a particular function can include a software component stored in a computer-readable medium in connection with the necessary hardware components, such as the processor 910, bus 905, output device 935, and so forth, to carry out the function. For clarity of explanation, in some instances the present technology may be presented as including individual functional blocks including functional blocks comprising devices, device components, steps or routines in a method embodied in software, or combinations of hardware and software.

In some embodiments the computer-readable storage devices, mediums, and memories can include a cable or wireless signal containing a bit stream and the like. However, when mentioned, non-transitory computer-readable storage media expressly exclude media such as energy, carrier signals, electromagnetic waves, and signals per se.

Methods according to the above-described examples can be implemented using computer-executable instructions that are stored or otherwise available from computer readable media. Such instructions can comprise, for example, instructions and data which cause or otherwise configure a general purpose computer, special purpose computer, or special purpose processing device to perform a certain function or group of functions. Portions of computer resources used can be accessible over a network. The computer executable instructions may be, for example, binaries, intermediate format instructions such as assembly language, firmware, or source code. Examples of computer-readable media that may be used to store instructions, information used, and/or information created during methods according to described examples include magnetic or optical disks, flash memory, USB devices provided with non-volatile memory, networked storage devices, and so on.

Devices implementing methods according to these disclosures can comprise hardware, firmware and/or software, and can take any of a variety of form factors. Typical examples of such form factors include laptops, smart phones, small form factor personal computers, personal digital assistants, rackmount devices, standalone devices, and so on. Functionality described herein also can be embodied in peripherals or add-in cards. Such functionality can also be implemented on a circuit board among different chips or different processes executing in a single device, by way of further example.

The instructions, media for conveying such instructions, computing resources for executing them, and other structures for supporting such computing resources are means for providing the functions described in these disclosures.

### EQUIVALENTS

Those skilled in the art will recognize, or be able to ascertain, using no more than routine experimentation, numerous equivalents to the specific embodiments described specifically herein. Such equivalents are intended to be encompassed in the scope of the following claims.

1. A microwave device, comprising:
a microwave power source;
a microwave cavity comprising:
a plurality of surfaces;
an empty domain; and
a feed connected to the microwave power source for receiving microwave energy from the microwave power source to create a microwave field distribution within the microwave cavity; and
a plurality of electromagnetic metamaterial layers disposed at different orientations with respect to a surface of the microwave cavity, the plurality of electromagnetic metamaterial layers affecting the microwave field distribution and forming a substantially spatially uniform, time-averaged electric field intensity throughout the empty domain of the microwave cavity from the microwave energy.

2. (canceled)

3. The microwave device of claim 1, wherein an electromagnetic metamaterial layer of the plurality of electromagnetic metamaterial layers comprises an artificial magnetic material or a magnetic metamaterial.

4. The microwave device of claim 3, wherein an electromagnetic metamaterial layer of the plurality of electromagnetic metamaterial layers comprises an electrically insulating substrate with electrically conductive lines, the conductive lines patterned to produce an artificially-magnetic effective response.

5. (canceled)

6. (canceled)

7. The microwave device of claim 1, wherein the plurality of electromagnetic metamaterial layers comprise one or more materials that allow tangential electric fields to exist on the surface of metamaterial layers, while concurrently reflecting electromagnetic waves back into the cavity thus substantially confining electromagnetic fields to the empty domain of the cavity.

8. The microwave device of claim 1, wherein the plurality of electromagnetic metamaterial layers reduce a Voltage Standing Wave ratio (VSWR) of a standing wave pattern of the microwave field distribution as part of forming the substantially spatially uniform, time-averaged, electric field intensity throughout the empty domain of the microwave cavity.

9-12. (canceled)

13. The microwave device of claim 1, wherein an electromagnetic property of an electromagnetic metamaterial layer of the plurality of electromagnetic metamaterial layers comprises an electromagnetic resonance, the electromagnetic resonance providing a small magnitude of a complex effective dielectric permittivity for at least one component of an electric field of the electromagnetic metamaterial layer.

14. (canceled)

15. The microwave device of claim 1, wherein the plurality of electromagnetic metamaterial layers comprises one pair of electromagnetic metamaterial layers, two pairs of electromagnetic metamaterial layers, or three pairs of electromagnetic metamaterial layers, and the metamaterial layers in each pair of electromagnetic metamaterial layers are positioned substantially parallel with respect to each other.

16. (canceled)

17. The microwave device of claim 1, wherein an electromagnetic metamaterial layer of the plurality of electromagnetic metamaterial layers comprises an optically transparent metamaterial layer.

18. (canceled)

19. (canceled)

20. The microwave device of claim 1, wherein the feed connected to the microwave power source is positioned on a wall of the microwave cavity to affect the electric field intensity in creating the substantially spatially uniform, time-averaged electric field intensity through the empty domain of the microwave cavity.

21. The microwave device of claim 1, wherein the feed connected to the microwave power source includes a transition from a conventional RF transmission line to an opening in a wall of the microwave cavity, the substantially spatially uniform, time-averaged electric field intensity formed over the opening.

22. (canceled)

23. The microwave device of claim 1, wherein the plurality of electromagnetic metamaterial layers affect a cut-off frequency of the microwave cavity to support a propagation wavelength of the microwave field distribution through the empty domain of the cavity that is greater than twice a minimum dimension of the microwave cavity.

24. (canceled)

25. (canceled)

26. A microwave device comprising:
a microwave power source;
a microwave cavity comprising:
a plurality of surfaces;
an empty domain; and
a feed connected to the microwave power source for receiving microwave energy from the microwave power source to create a microwave field distribution within the microwave cavity; and
a plurality of electromagnetic metamaterial layers disposed at different orientations with respect to a surface of the microwave cavity, the plurality of electromagnetic metamaterial layers affecting a cut-off frequency of the microwave cavity to support propagation of the microwave field through the empty domain of the microwave cavity at a wavelength that is greater than twice a minimum dimension of the microwave cavity.

27. (canceled)

28. The microwave device of claim 26, wherein an electromagnetic metamaterial layer of the plurality of electromagnetic metamaterial layers comprises an artificial magnetic metamaterial.

29. The microwave device of claim 28, wherein an electromagnetic metamaterial layer of the plurality of electromagnetic metamaterial layers comprises an electrically insulating substrate with electrically conductive lines, the conductive lines patterned to produce an artificially-magnetic effective response.

30. (canceled)

31. The microwave device of claim 26, wherein an electromagnetic metamaterial layer of the plurality of electromagnetic metamaterial layers comprises a high impedance metamaterial.

32. The microwave device of claim 26, wherein the plurality of electromagnetic metamaterial layers comprise one or more materials that allow tangential electric fields to exist on the surface of metamaterial layers, while concurrently reflecting electromagnetic waves back into the cavity thus substantially confining electromagnetic fields to the empty domain of the cavity.

33. The microwave device of claim 26, wherein the plurality of electromagnetic metamaterial layers reduce a Voltage Standing Wave ratio (VSWR) of a standing wave pattern of the microwave field distribution.

34-37. (canceled)

38. The microwave device of claim 26, wherein an electromagnetic property of an electromagnetic metamaterial layer of the plurality of electromagnetic metamaterial layers comprises an electromagnetic resonance, the electromagnetic resonance providing a small magnitude of a complex effective dielectric permittivity for at least one component of an electric field of the electromagnetic metamaterial layer.

39. (canceled)

40. The microwave device of claim 26, wherein the plurality of electromagnetic metamaterial layers comprises one pair of electromagnetic metamaterial layers, two pairs of electromagnetic metamaterial layers, or three pairs of electromagnetic metamaterial layers, and the metamaterial layers in each pair of electromagnetic metamaterial layers are positioned substantially parallel with respect to each other.

41. (canceled)

42. The microwave device of claim 26, wherein an electromagnetic metamaterial layer of the plurality of electromagnetic metamaterial layers comprises an optically transparent metamaterial layer.

43-45. (canceled)

46. A method of manufacturing a microwave oven comprising:
selecting design parameters of a plurality of electromagnetic metamaterial layers and a microwave cavity for creating a microwave field distribution within the cavity from microwave energy fed into the microwave cavity from a microwave power source; and
manufacturing the microwave oven according to the selected design parameters of the plurality of electromagnetic metamaterial layers and the microwave cavity so the plurality of electromagnetic metamaterial layers affect the microwave field distribution and form a substantially spatially uniform, time-averaged electric field intensity throughout an empty domain of the microwave cavity from the microwave energy during operation of the microwave oven.

47-51. (canceled)

52. A method of manufacturing a microwave oven comprising:
selecting design parameters of a plurality of electromagnetic metamaterial layers and a microwave cavity for creating a microwave field distribution within the cavity from microwave energy fed into the microwave cavity from a microwave power source; and
manufacturing the microwave oven according to the selected design parameters of the plurality of electromagnetic metamaterial layers and the microwave cavity so the plurality of electromagnetic metamaterial layers affect a cut-off frequency of the microwave cavity to support propagation of the microwave field through the empty domain of the microwave cavity at a wavelength that is greater than twice a minimum dimension of the microwave cavity.

53-55. (canceled)
